(19) United States
(12) Patent Application Publication
(10) Pub. No.: US 2005/0106867 A1
(43) Pub. Date: May 19, 2005

(54) Method and device for treating objects by means of a liquid

(76) Inventor: Christian Schmid, Freudenstadt (DE)

Correspondence Address: FLYNN THIEL BOUTELL & TANIS, P.C., 2026 RAMBLING ROAD, KALAMAZOO, MI, 49008-1699, US

(21) Appl. No.: 10/494,772

(22) PCT Filed: Oct. 29, 2002
(86) PCT No.: PCT/EP02/12040

(30) Foreign Application Priority Data
Nov. 5, 2001 (DE) 101-54-885.0

(51) Int. Cl. H01L 21/302; H01L 21/461

(52) U.S. Cl. 438/689

(57) ABSTRACT

The invention, in a specific embodiment, relates to a method and to a device for treating substrates (29) in printed circuit industry by means of a liquid. The invention is characterized in that the substrates (29), on their surface, are provided with a layer that is partially removed under the influence of the liquid while a pattern is formed. A plurality of nozzles (24) are provided for discharging the liquid and are linked with at least one liquid connection (12). Said liquid connection (12) is linked with a liquid reservoir and can be opened and closed. A valve (17) is provided directly on every nozzle (24), said valves (17) being individually controlled to open and close. The objects (29) are displaced along a track of movement (B) relative to the nozzles (24). A specific amount of liquid is discharged by opening and closing the valves (17) or the liquid connections (12) and has a certain distribution across the surface (26).

### FIELD OF APPLICATION AND STATE OF THE ART

The invention relates to a method and a device for treating objects such as, for example, substrates in the printed circuit board industry, by means of a liquid.

As a rule, objects, substrates or so-called printed circuit boards have a layer, for example a layer of conductive material like copper, on their surface. This layer can be removed under the influence of a liquid, which can be in particular an etching medium, in order to form a pattern in the layer. The liquid is discharged by means of nozzles, which are connected to a liquid connection.

A problem exists in that often such nozzles are provided as a type of a field of nozzles in larger numbers, side-by-side, and also one behind the other. The substrates are layed flat and moved under this field of nozzles and are thereby sprayed with the liquid. The problem arises herein that basically a full, even distribution of liquid is applied to the substrates. However, the liquid can easily flow off towards the edge in the outer areas of the substrate. As such, the liquid exchange is greater in the outer areas of the substrate as significantly more fresh etching liquid is applied. In contrast, a sort of liquid accumulation (so-called puddle effect) is formed in the center area of the substrate, and as such, the exchange of liquid is by far less. This has the result that significantly more of the layer is etched away in the outer areas than in the center area, and thus the result is not as good or a substrate may possibly become nonusable.

To overcome this problem it is known from the DE 33 45 125 to apply less liquid in the outer areas of the substrate or to reduce the through-flow of liquid. Control valves and flowmeters are, for this purpose, provided in the supply pipes to the nozzles. This device is very expensive because of the flowmeters needed for this. Also, controlling the valves is not easy, as complicated valves are needed.

### PURPOSE AND SOLUTION

The basic purpose of the invention is to provide an above-identified method and a device, with which the application of liquid onto such objects is individually and intentionally possible. The inventive method and the device are thereby kept as simple as possible.

This purpose is attained by a method having the characteristics of Claim 1 and a device with the characteristics of Claim 10. Advantageous and preferred embodiments of the invention are the subject matter of further claims and will be discussed in greater detail hereinafter. The wording of the claims is made part of the content of the application via expressed reference.

A liquid connection for the nozzles is in the inventive method connected to a liquid reservoir and can be opened and closed. A valve is directly associated with each nozzle at as small a distance as possible from the nozzle. An extremely delay-free control of the liquid application by the nozzle is advantageously made possible in this manner. The valves are thereby individually controlled for opening or closing. The valves, however, can also be simultaneously controlled in groups. Thus an individually desired liquid application or a thus formed liquid-discharge picture is possible.

The substrates or objects are moved, advantageously with a continuous speed, along a path of movement relative to the nozzles. By opening and closing the valves it is possible, on the one hand, to create with the liquid connection being open a specific liquid discharge with a predetermined surface distribution over the path of movement. As an alternative, it is possible to additionally open or close the liquid connections in order to achieve this surface distribution.

The liquid connections are for this purpose are advantageously designed to be elongated and have several nozzles which are spaced at a specific distance from one another. The liquid connections can be opened and closed preferably via a lock. Several of such liquid connections are, in a preferred embodiment, arranged parallel to one another and one behind the other. They can in this manner cover a surface of an object being passed along the path of movement. The liquid connections are particularly and preferably individually controlled to open or close, depending on the predetermined surface distribution of the liquid discharge desired.

The liquid connections are advantageously stationary and the objects move on a path of movement. This path of movement can be a transport path, for example a roller path or the like. Liquid connections are preferably provided at least above the path of movement of the objects and bring the liquid from above onto the objects.

One possibility of an embodiment of the invention provides, in order to achieve the surface distribution, that the valves of the nozzles are exclusively controlled. Thus a control of the process can be limited to the valves of the nozzles. Another possibility of an embodiment of the invention provides that the nozzles of the valves and also the locks of the liquid connections are opened and closed in order to achieve the surface distribution. The nozzles are thereby in a first step preadjusted to be opened or closed by means of the valves. The liquid connections or their locks are then, during the process itself, opened and closed. Thus the liquid distribution is preadjusted in a way through the valves of the nozzles, and the discharge of liquid itself is then activated by means of opening and closing the connections. The valves can in this manner be preserved as they do not have to be continuously operated or adjusted. Since one liquid connection carries a plurality of nozzles, it is easier to cycle the discharge of liquid through this liquid connection.

Less liquid is applied in the outer areas of a substrate (i.e., to the lateral and/or the front and rear outer areas of the substrates) than in a center area in the inventive method in order to avoid the application of too much liquid. The application of liquid can thereby basically be reduced as desired. It is preferred that an amount of applied liquid is less, which occurs particularly preferred through a time reduction. This means that the flow of liquid through a nozzle, if such flow occurs at all, is the same in every case. The respective nozzles are, however, more often or for a longer time period switched off or more seldom activated in the respective outer areas.

The nozzles are advantageously stationarily arranged. The nozzles are according to one possibility of the invention designed rigidly and with a fixed discharge direction. The nozzles can according to another, more complicated possibility be moved or changed in their alignment. This can be done for each nozzle individually or in groups. The change of the alignment can occur both in one direction or plane, in several planes, or entirely freely selectable. It is possible through the provision of drives to control the alignment of the nozzles by, for example, electromotorically. Such groups of nozzles can be divided according to liquid connections, for example, together with the liquid connection in the form of a pipe or the like. A yet finer and arbitrarily achievable discharge of liquid can be achieved with nozzles adjustable in this manner.

One possibility of an embodiment of the invention provides that, viewed in the direction of passage of the objects, only one or few nozzles discharge liquid in the front area. Increasingly more nozzles discharge liquid in the direction of passage, which nozzles thus advantageously cover a larger surface or have a greater expansion. Thus it is possible to produce a surface distribution which is wedge-shaped and widens in the direction of passage. It is furthermore possible to permit, in an inventive method, for several objects to pass through side-by-side. It is hereby possible to produce for every object a specific profile, such as, for example, a wedge-shaped profile. It is also possible to produce a separate and/or different profile for each object.

One possibility for operating valves of nozzles is by means of compressed air. This is relatively simple and yet reliable and requires very little service. Compressed-air pipes can be guided directly to the valves.

These and further characteristics can be taken, besides from the claims, also from the description and the drawings, whereby the individual characteristics each by themselves, or several together in the form of sub-combinations, are realized in one embodiment of the invention and in other areas, and can represent advantageous and by itself protectable embodiments, for which protection is here claimed. The division of the application into individual sections and in-between titles does not limit the statements made under these titles in their universal validity.

### BRIEF DESCRIPTION OF THE DRAWINGS

Exemplary embodiments of the invention are schematically illustrated in the drawings and will be described in greater detail hereinafter. In the drawings:

FIG. 1 is a lateral cross-sectional view of an inventive nozzle tube with a plurality of discharge systems with nozzles arranged on the nozzle tube;

FIG. 2 is an enlarged cross-sectional view of one of the discharge systems depicted in FIG. 1;

FIG. 3 is a further cross-sectional view of the discharge system of FIG. 2 with the nozzle; and

FIGS. 4 to 6 are various schematic illustrations of nozzle fields with distribution profiles and printed circuit boards of varying formats.

### DETAILED DESCRIPTION AND EXEMPLARY EMBODIMENTS

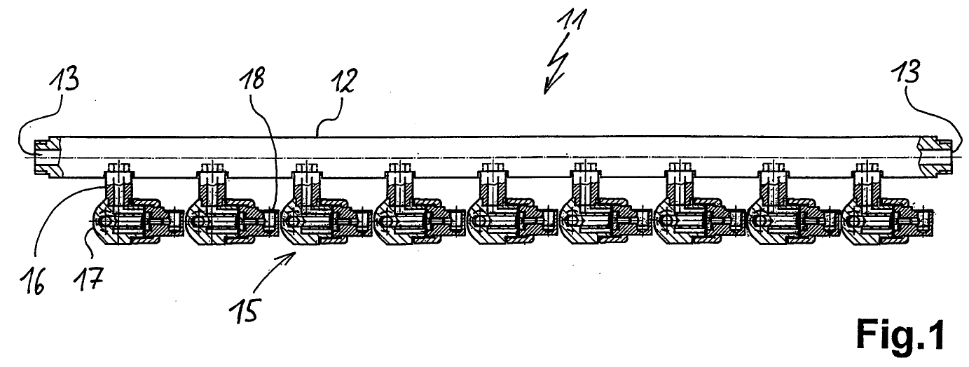

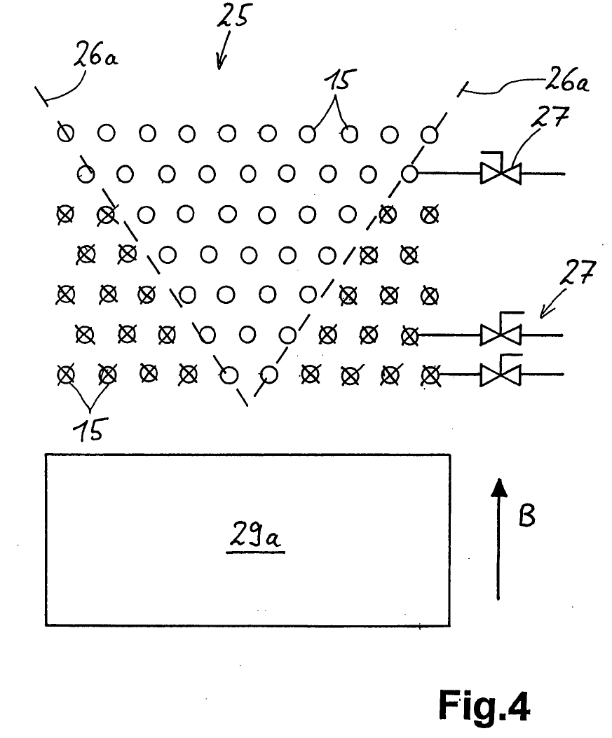

FIG. 1 shows in a lateral view an inventive device 11 with a nozzle tube 12. The nozzle tube 12 has liquid inlets 13 on the left and on the right which extend through the nozzle tube 12. The nozzle tube 12 can be opened and closed by locks schematically illustrated in FIG. 4. The locks 27 of the nozzle tubes 12 can be pneumatically operated.

The nozzle tube 12 carries a plurality of discharge systems 15, which are equally spaced from one another and are identically designed. The discharge systems 15 connect to the nozzle tube 12 by means of a connecting piece 16 which allows for the conduction of liquid between the nozzle tube 12 and discharge systems 15.

Each of the discharge systems 15 include a valve system 17 controlled by a compressed-air connection 18. The discharge systems 15 can, in other embodiments, be arranged at varying intervals on the nozzle tube 12. It is also possible to provide discharge systems of different designs, and/or connect discharge systems to both sides of the nozzle tube 12.

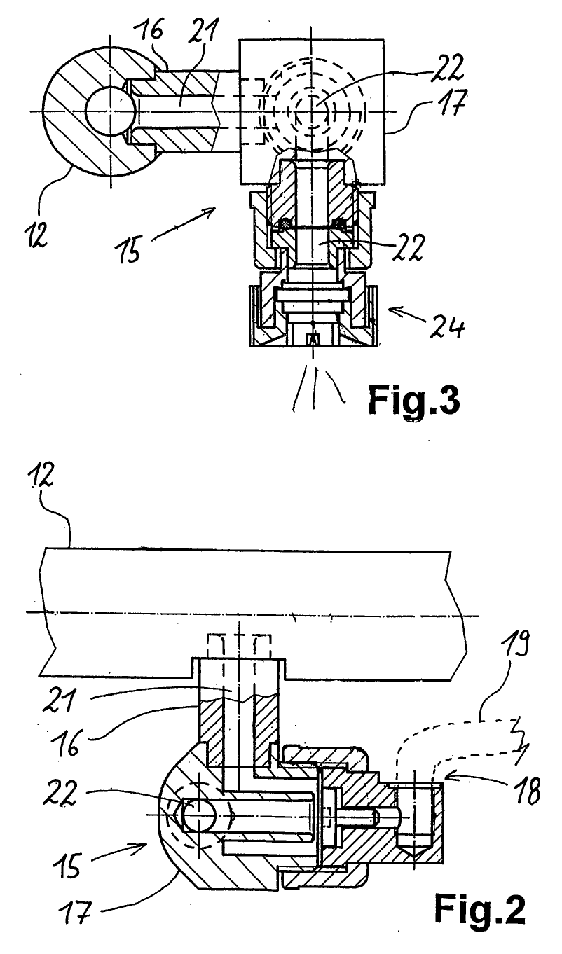

FIG. 2 illustrates an individual discharge system 15 on the nozzle tube 12 according to the illustration of FIG. 1. A compressed-air pipe 19 extends into a compressed-air connection 18. The opposite end of the compressed-air pipe 19 is connected to a compressed-air system (not illustrated). Each compressed-air pipe 19 can be individually controlled. Consequently, each discharge system 15 can be individually controlled through its corresponding compressed-air pipe 19.

The liquid-conducting connection to the nozzle tube 12 occurs through a liquid channel 21 contained within or attached to connecting piece 16. The liquid channel 21 extends through a valve system 17, wherein a diaphragm valve is opened and closed by means of the compressed-air connection 18. This diaphragm valve does not need to be discussed in greater detail at this time. The liquid channel 21 ends in a nozzle inlet 22, which, in FIG. 2, extends into the drawing plane.

FIGS. 2 and 3 shows on the one hand that the discharge system 15, or rather the nozzle 24, is arranged very close to the nozzle tube 12. On the other hand, one can see that the valve system 17, and thus the influence on whether the nozzle 24 operates, is provided directly on the nozzle. Thus a very precise and up-to-date influence of the nozzle is possible.

FIG. 3 shows how the nozzle 24 is arranged below the valve system 17. The nozzle 24 connects to the liquid channel 21, and thus to the nozzle tube 12, by the nozzle inlet 22. The precise design of the nozzle 24 does not need to be discussed here since it can be seen in FIG. 3 and corresponds essentially to conventional nozzle systems.

A nozzle jet extends downwardly from the nozzle 24. The nozzle jet can be adjusted regarding its profile or its width on the nozzle 24 itself. This can be done by a manual or automatic control.

FIG. 4 illustrates schematically a nozzle field 25. The field comprises a plurality of discharge systems 15. These are arranged side-by-side on the nozzle tube 12 corresponding to FIG. 1. The conduction of liquid through these nozzle tubes, which are not illustrated in FIG. 4, can be controlled by means of locks 27.

It can be recognized that some of the discharge systems 15 are crossed out. This means that they are blocked by means of the valve systems 17 during operation and do not cause the discharge of liquid. Thus a distribution profile 26a results from the active discharge systems 15, which distribution profile 26a is made clear by the dashed line. As can be taken from this, the distribution profile 26a in FIG. 4 is wedge-shaped.

One printed circuit board 29a moves through the nozzle field 25 in direction B. The discharge of liquid onto the printed circuit board 29a is specified by the distribution profile 26a. From this one can recognize that the discharge of liquid is stronger in a central area of the printed circuit board 29a or a center strip than towards the edge since here more nozzles are activated.

Liquid is discharged in such a manner that the discharge systems 15 are preadjusted by the valve systems 17 so as to be opened or closed to correspond to the distribution profile 26a. The discharge systems 15 are then controlled by means of the locks 27 through the nozzle tubes 12. As has been discussed above, the valve systems 17 are thus protected as they do not have to be operated as often.

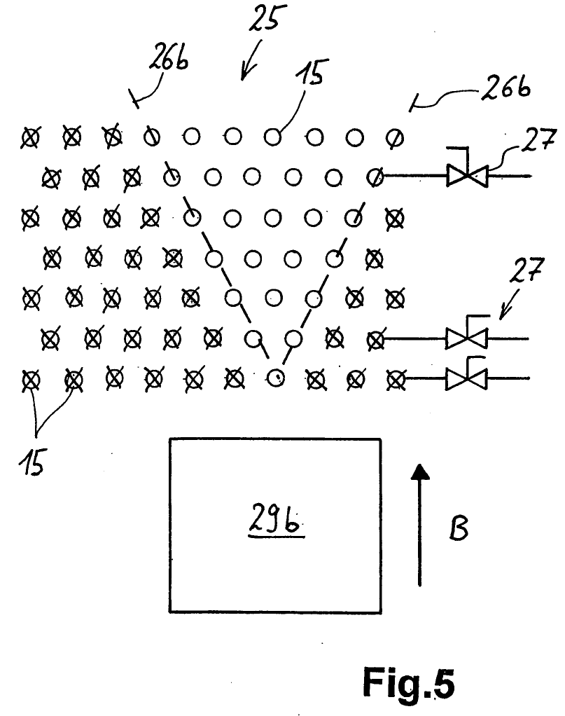

FIG. 5 again illustrates the nozzle field 26 of FIG. 4. Since the printed circuit board 29b has here a smaller width, the wedge-shaped distribution profile 26b is designed to be more tapered or adjusted to its width. The printed circuit board 29b is here furthermore shifted to the right relative to the center axis of the nozzle field 25. For this reason, the distribution profile 26 is also shifted to the right.

In order to make an adjustment to a printed circuit board that is shorter in the direction of movement B, it is possible to turn off entire rows of discharge systems 15, or nozzle tubes 12, which extend perpendicularly with respect to the direction of movement B.

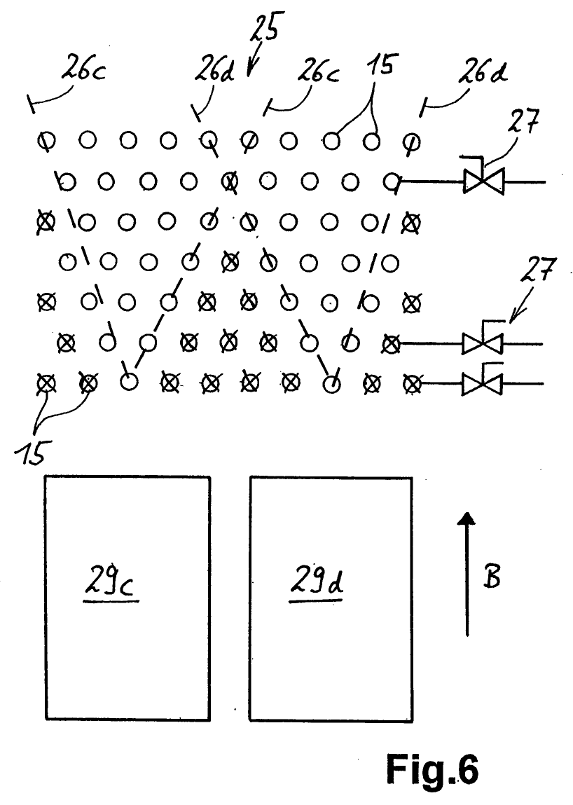

FIG. 6 also illustrates the nozzle field 25 of FIG. 4. Here two side-by-side printed circuit boards 29c and 29d are to be applied with liquid. From this results the distribution profile 26c or 26d, which again is illustrated by dashed lines. As before, these distribution profiles are directed wedge-shaped against the path of movement B. The two distribution profiles 26c and 26d overlap in the upper center area of the discharge systems 15. This, however, does not create any problems whatsoever in practice.

If the two printed circuit boards 29c and 29d were moved in direction of movement B separate from one another, then the distribution profiles 26 would actually be the same. Merely the timely use of each profile 26 would vary and would be adjusted individually for each printed circuit board.

The Figures do not show a unit for controlling the discharge of the liquid. However, it is envisioned that such a control unit can have, in particular, a sensory mechanism which detects position, alignment and size of the printed circuit boards and, adjusted thereto, determines the discharge of liquid, or a corresponding distribution profile used in the discharge of liquid.

1. A method for treating objects, in particular substrates (29) in the printed circuit board industry, by means of a liquid, characterized by:
the objects (29) have a layer on their surface, which layer is partially removed under the influence of the liquid while a pattern is formed,
several nozzles (24) are provided for discharging the liquid and are connected to at least one liquid connection (12),
the liquid connection (12) is connected to a liquid reservoir and can be opened and closed,
a valve (17) is provided directly on every nozzle (24),
the valves (17) can be controlled individually for opening or closing,
the objects (29) are moved along a path of movement (B) relative to the nozzles (24),
a specific amount of liquid is discharged with a surface distribution (26), which is predetermined or can be predetermined over a path of movement, by means of opening and closing the valves (17) and/or the liquid connections (12).

2. The method according to claim 1, characterized in that the liquid connections (12) are elongated, have several nozzles (24) spaced from one another, and can be opened and closed each through a lock (27), whereby several liquid connections (12) are arranged parallel to one another and one behind the other in order to cover a surface above the path of movement (B) and can in particular be individually controlled.

3. The method according to claim 1, characterized in that the liquid connections (12) are arranged one behind the other relative to the path of movement (B), and the objects (29) are moved along the path of movement (B).

4. The method according to claim 1, characterized in that for achieving a specific surface distribution (26) of the liquid discharge over the path of movement (B) the valves (17) of the nozzles (24) are controlled.

5. The method according to claim 4, characterized in that for achieving the surface distribution (26) the valves (17) of the nozzles (24) are exclusively controlled.

6. The method according to claim 1, characterized in that for achieving the surface distribution (26) in the passage of the objects (29) the nozzles (24) are preadjusted by means of the valves (17) in a first step, and the liquid connections (12) are opened and closed for cycling in a second step.

7. The method according to claim 1, characterized in that for achieving a specific surface distribution (26) of the liquid discharge less liquid is applied to the lateral and/or front and rear outer areas of the objects (29) than in the center area, whereby the liquid discharge is preferably less in amount and time.

8. The method according to claim 1, characterized in that the nozzles (24) are moved or changed in their alignment, whereby the nozzles (24) are preferably changed individually or in groups, and in particular the groups are divided in accordance with liquid connections (12).

9. The method according to claim 1, characterized in that in direction of passage of the objects (29) along the path of movement (B) of the front nozzles (24) only one or few nozzles discharge liquid and in direction of passage increasingly more nozzles, preferably with coverage of a larger surface, discharge liquid.

10. A device for treating of objects, in particular substrates (29) in the printed circuit board industry, by means of a liquid, in particular for carrying out the method according to one of the preceding claims, characterized by:
the objects (29) have a layer on their surface, which layer is partially removed under the influence of the liquid while a pattern is formed,
several nozzles (24) are provided for discharging the liquid and are connected to at least one liquid connection (12),
the liquid connection (12) is connected to a liquid reservoir and can be opened and closed,
a valve (17) is provided directly on every nozzle (24),
the valves (17) can be controlled individually for opening or closing,
the objects (29) are moved along a path of movement (B) relative to the nozzles (24),
the valves (17) and/or the liquid connection (12) can be opened and closed in order to produce a specific liquid discharge with a surface distribution (26) predetermined through a path of movement (B).

11. The device according to claim 10, characterized in that the liquid connection (12) is elongated, has several nozzles (24) spaced from one another and can be opened and closed through a lock (27), whereby preferably several liquid connections (12) are arranged parallel to one another and one behind the other for covering a surface above the path of movement (B) and can in particularly be individually controlled.

12. The device according to claim 10, characterized in that the liquid connections (12) are arranged stationarily one behind the other relative to the path of movement (B), whereby the objects (29) can be moved preferably on a transport path, in particular a roller path, under the liquid connections (12).

13. The device according to claim 10, characterized in that the valves (17) of the nozzles (24) can be controlled, in particular individually, in order to achieve a specific surface distribution (26) of the discharge of liquid over the path of movement (B).

14. The device according to claim 10, characterized in that the nozzles (24) are arranged on the liquid connection (12) with a small distance therefrom, whereby the valve (17) is arranged preferably between nozzle (24) and liquid connection (12).

15. The device according to claim 10, characterized in that the nozzles (24) can be moved or changed in their alignment, whereby the nozzles (24) can preferably be changed individually or in groups, and in particular the groups are divided in accordance with liquid connections (12).
